(19) United States
(12) Patent Application Publication
(10) Pub. No.: US 2024/0418812 A1
(43) Pub. Date: Dec. 19, 2024

(54) COMPUTER-IMPLEMENTED METHOD FOR PROVIDING A DRIVE SEQUENCE FOR USE, METHOD FOR CAPTURING MEASUREMENT DATA, PROVISION AND/OR ACQUISITION SYSTEM, COMPUTER PROGRAM, AND ELECTRONICALLY READABLE DATA STORAGE MEDIUM

(71) Applicant: Siemens Healthineers AG, Forchheim (DE)

(72) Inventors: Patrick Liebig, Erlangen (DE); Jürgen Herrler, Erlangen (DE)

(21) Appl. No.: 18/744,597

(22) Filed: Jun. 14, 2024

(30) Foreign Application Priority Data
Jun. 16, 2023 (DE) 10 2023 205 665.8

(51) Int. Cl. G01R 33/54; G01R 33/483

(52) U.S. Cl. CPC G01R 33/543; G01R 33/4835

(57) ABSTRACT

A computer-implemented method for providing a drive sequence for a magnetic resonance device is provided. The drive sequence includes radiofrequency pulses to be output via transmit channels of a radiofrequency coil arrangement. The method includes, before the examination including the measurement procedure, precalculating a set of base sequences for mutually spaced reference points of at least one requirement parameter that describes the target excitation state. The reference points cover a parameter interval for use. The base sequences are provided together with the associated reference points at the magnetic resonance device. A measurement procedure value of the requirement parameter is provided at the magnetic resonance device. A drive sequence is ascertained for use for the measurement procedure. In the event that the measurement procedure value for the requirement parameter differs from the reference points, the drive sequence is ascertained from the base sequences by interpolation and/or extrapolation using a derivation algorithm.

This application claims the benefit of German Patent Application No. DE 10 2023 205 665.8, filed on Jun. 16, 2023, which is hereby incorporated by reference in its entirety.

### BACKGROUND

The present embodiments relate to providing a drive sequence that is target-region selective, for producing a target excitation state for a procedure for capturing measurement data from an object under examination using a magnetic resonance device.

In magnetic resonance imaging (e.g., also with a medical use), it has been proposed to employ higher magnetic field strengths of the main magnetic field (B0 field), because this may achieve a higher image quality of the measurement data. The term ultra-high field magnetic resonance imaging (UHF MRI) is used for magnetic field strengths of 7 Tesla or more. The high main magnetic field results in a short Larmor wavelength, however, which may lead to high spatial inhomogeneity of the radiofrequency excitation field (B1 field). This is caused, for example, by the relatively good tissue conductivity at radiofrequencies, and by reflections at boundary surfaces between different biological tissues, or biological tissue and air. In addition, even small deviations in the homogeneity of the main magnetic field lead to significant differences in Larmor frequencies.

As a result, it may not be possible to achieve a desired target excitation state (e.g., a specific homogeneous flip angle of the spins of the object under examination).

It has been proposed in this regard in the prior art to employ radiofrequency coil arrangements having a plurality of transmit channels and to use the parallel transmit (pTx) transmission technique. In this technique, a plurality of radiofrequency coils (e.g., transmit coils) are driven via respective transmit channels with radiofrequency pulses with different pulse shapes specific to each, and the radiofrequency excitation field (B1 field) is obtained from the interference of the fields generated by the individual radiofrequency coils. It may hence be controlled in terms of its spatial distribution.

A distinction may be drawn between what is known as static pTx and dynamic pTx. In the case of static parallel transmission, the same radiofrequency pulse shape (e.g., a rectangular shape or a sinc shape) is applied to all the transmit channels, and is scaled by magnitudes and phases specific to the transmit channel. This generates an excitation field (e.g., a static excitation field) that is more spatially homogeneous than an uncalibrated excitation field. In the case of dynamic parallel transmission, time-varying B1 fields are generated, each of which is itself inhomogeneous, and are applied simultaneously with likewise time-varying B0 gradient fields that describe a transmit k-space trajectory. This may achieve extremely homogeneous flip-angle distributions at the end of the dynamic parallel transmission.

It is also known in parallel transmission to provide a plurality of radiofrequency pulses (e.g., successively in time) per transmit channel in order to homogenize the spatial distribution of the flip angles across a plurality of radiofrequency pulses. This approach is also referred to as multi-pulse pTx.

Optimization methods are normally employed in order to determine the optimization parameters that specify the pulse shapes and timing of the dynamic and/or multi-pulse pTx drive sequences so as to achieve desired target excitation states. However, the optimization of dynamic drive sequences and multi-pulse drive sequences of the parallel transmission is extremely complex, computationally intensive, and dependent on the anatomical nature and position and/or orientation of the acquisition region at the object under examination (e.g., of a part of the body of a patient). Tailored radiofrequency pulses and, if applicable, gradient pulses that are optimum for a specific measurement procedure therefore cannot be calculated until field distribution maps of the object under examination have been acquired (e.g., only once the object under examination is ready for the examination). Given lengthy optimization processes for the pTx pulses, this results in very long delays in the examination that are not clinically practicable.

Therefore, various approaches have already been proposed in the prior art to speed up the readiness for measurement procedures on objects under examination in magnetic resonance devices by already calculating in advance, and keeping available at the magnetic resonance device, base sequences that may be used as the drive sequences, or from which the drive sequence may be derived for use.

The concept of universal pulses has shown that a large proportion of the inhomogeneities may be corrected by pre-calibrated pTx pulses (e.g., pTx pulses already optimized before the actual examination) if the universal pulses are ascertained using field distribution maps from a plurality of subjects under examination. In other words, in the universal pulse concept, the optimization is performed for a cohort of reference objects under examination, and once optimized, the pulses are then used without further calibration for all the objects under examination. Details of this approach appear, for example, in WO 2017/060142 A1 or the article by Vincent Gras et al., “Universal pulses: A new concept for calibration-free parallel transmission,” Magnetic Resonance in Medicine 77 (2017), pages 635 to 643.

In order to improve this approach further, methodologies have been proposed that allow a quick-to-implement further improvement in precalculated base sequences (e.g., containing universal pulses) immediately before an examination. An article by Caroline Le Ster et al., “Standardized universal pulse: A fast RF calibration approach to improve flip angle accuracy in parallel transmission,” Magnetic Resonance in Medicine 87 (2022), pages 2839-2850, explains the concept of standardized universal pulses (SUP). It proposes using what is known as a standardized database, in which each B1+ map has been normalized to a reference transmit radiofrequency field distribution. When scanning a new object under examination, rapid acquisition of three B1+ slices is performed in order to adjust the standardized universal pulses by a linear transform.

A further option is known as FOCUS, and is described, for example, in an article by Jürgen Herrler et al., “Fast online-customized (FOCUS) parallel transmission pulses: A combination of universal pulses and individual optimization,” Magnetic Resonance in Medicine 85 (2021), pages 3140-3153. Reference is also made to EP 3 809 151 A1. This option makes use of universally optimized transmit k-space trajectories, which may be described by a small number of parameters, radiofrequency-pulse shapes, and associated parameters relevant to the optimization (e.g., for energy regularization and/or as subpulse durations) in order then, after the acquisition of field distribution maps, to optimize further the pulses (e.g., the pulse shapes) of the base sequences in a customized manner.

In a development of this approach, EP 3 901 648 A1 proposes a method and an apparatus for controlling a magnetic resonance imaging system. Pulse data is selected or calculated in a pulse-design unit for generating pulse data for controlling the magnetic resonance imaging system. Based on a set of B0 and B1 maps from different patients, pulses are designed by interpolation on a grid and/or based on a neural network. A lexicon of selective pulses may be formed on the grid so that optimum pulses for a measurement may be determined based on an examination scheme. For example, the examination scheme includes information about contrasts to be measured and the order and shape of sub-regions of a region of interest that are meant to be acquired.

Also, more generally, it has already been proposed to allocate precalculated universal pulses to different clusters. Based on the quantities describing the current measurement procedure, it is possible to select from the cluster-specific pulse sequences a pulse sequence that is particularly suitable for the measurement procedure. Such quantities may be quantities relating to the object under examination. It has also been proposed, however, for example, as part of the aforementioned FOCUS method, to use field distribution maps (e.g., B1 maps) as the basis for the selection of a cluster-specific pulse sequence. For example, the B1 maps for the current measurement procedure may be analyzed by a trained cluster-identification function (e.g., including a neural network) in order to determine a cluster-specific pulse sequence.

An article by Raphael Tomi-Tricot et al., “SmartPulse, a machine learning approach for calibration-free dynamic RF shimming: Preliminary study in a clinical environment,” Magnetic Resonance in Medicine 82 (2019), pages 2016 to 2031 proposes in this regard a calibration-free pulse-design method, in which a database of field distribution maps is grouped into clusters based on mutual affinity between their associated “kT-points” pulses. A machine-learning classifier was trained based on further field distribution maps to select the best common “kT-points” pulse of the three available clusters.

The precalculation is to be ascertained, for example, in each case for specific target excitation states (e.g., specific sets of target excitation parameters describing the target excitation state). This task is still manageable, for example, when the excitation is not meant to be spatially selective or at least not variably selective. In practice, however, many cases arise in which there is the widest variation in the orientation, positions, and/or extents of target regions (e.g., slices), to which the target excitation is meant to be confined while still maintaining the highest possible homogeneity of the excitation.

In traditional magnetic resonance imaging at lower main magnetic field strengths, it is known to use sinc pulses for this purpose as the radiofrequency pulses. The frequency spectrum of radiofrequency pulses of this shape is rectangular (e.g., corresponds to a rectangular function). If a gradient field is now applied by a suitable gradient pulse simultaneously with such a radiofrequency pulse so that the magnetic field strength increases linearly along the slice direction, the Larmor frequencies of the nuclear spins also increase in the slice direction, and only those nuclear spins having a Larmor frequency within the frequency band of the radiofrequency pulse are excited. This selectively excites specific slices.

In order to be able to ascertain slice-selective excitations also for very high main magnetic field strengths as quickly as possible (e.g., and also without a precalculation), either static parallel transmission may be operated for each slice, or simple dynamic pTx pulses (e.g., spokes pulses) are used, each consisting of a plurality of sinc-shaped subpulses. This is also known as a composite pulse. Pulse sequences containing such spokes pulses consisting of a plurality of subpulses are optimized such that an optimized pulse is calculated for each slice to be created. In order to calculate this, the individual gradient blips (e.g., “spokes”) needed between the individual subpulses, and the optimum amplitudes and phases of each subpulse, are found for each slice. An optimization is possible quickly for the composite pulses/spokes pulses, because it is necessary to optimize only amplitude and phase factors for scaling the individual subpulses, and the moment of the intervening gradient blips. In addition, this may only be done for the voxels within a slice (e.g., a few thousand voxels). Such approaches have the disadvantage, however, that the extent to which the approaches may correct field inhomogeneities within the slice to be excited is limited. The reason for this is that, in the case of static parallel transmission, only the central transmit k-space point is used; in the case of spokes pulses, similarly, it is possible to select only two to three k-space points in-plane. If more subpulses were used, this would lead to a longer total output duration of the drive sequence, increasing the measurement time. For specific types of magnetic resonance sequences (e.g., gradient echo sequences), short excitation times or short measurement times are needed, however.

An alternative for ascertaining better drive sequences containing improved radiofrequency pulses (e.g., and also gradient pulses) would be to optimize for the entire three-dimensional volume based on far more complicated radiofrequency pulses and, if applicable, also gradient pulses (e.g., or at least allowing these more complicated pulses), where, for example, a resolution of 0.2 mm along the slice direction may be adopted for defining the target excitation state as a target magnetization. The target region (e.g., the slice) that is meant to be excited is set to unity or to a certain target flip-angle. For each point of this target magnetization, an extra dimension containing the values of the transmit-channel specific B1 maps and of the B0 map (e.g., field distribution maps) is added. This results in a very high number of voxels, which may lie between 100,000 and 1,000,000, for example. Radiofrequency pulses of a more complicated nature, if applicable together with gradient pulses, may then be optimized for this target excitation state in an optimization process. The optimization may be performed under constraints arising from the performance and/or power rating of the magnetic resonance device (e.g., by limit values for the maximum radiofrequency pulse voltages), the slew rate of the B0 field gradients, and/or the pulse power or pulse energy, while generally also boundary conditions or terms of the target function may be formulated on SAR constraints for the object under examination. Such an optimization process for a clearly defined special case (e.g., a specific measurement procedure using specific target excitation parameters) may take about an hour or even longer. This is of no use in practice for examinations of objects (e.g., patients) under examination because the objects would have to spend the entire extremely long optimization period in the magnetic resonance device in order for the field distribution maps to remain applicable.

The approaches described above may, for example, be employed for precalculated base sequences (e.g., universal pulses, FOCUS, or SmartPulse) for all conceivable target excitation parameters, or for variable requirement parameters selected therefrom. Then, however, the high variability (e.g., with regard to the target region) would provide expected precalculation times of a number of months (e.g., several months or even several years).

### SUMMARY AND DESCRIPTION

The scope of the present invention is defined solely by the appended claims and is not affected to any degree by the statements within this summary.

The present embodiments may obviate one or more of the drawbacks or limitations in the related art. For example, a facility for quickly providing, during an examination, drive sequences for use, that are suitable for target excitation states defined, with regard to the target region, via requirement parameters, and homogenize the excitation field sufficiently for clinical use and have a short total output duration is provided.

A method includes, according to the present embodiments, the following acts. Before the examination including a measurement procedure, a set of base sequences is precalculated for mutually spaced reference points of at least one requirement parameter that describes the target excitation state. The reference points cover a parameter interval for use. The base sequences are provided together with the associated reference points at the magnetic resonance device. A measurement procedure value of the requirement parameter is provided at the magnetic resonance device. A drive sequence is ascertained for use for the measurement procedure. In the event that the measurement procedure value for the requirement parameter differs from the reference points, the drive sequence is ascertained from the base sequences by interpolation and/or extrapolation using a derivation algorithm.

For example, it may also be provided that the base sequences and the drive sequence also include at least one gradient pulse for at least one gradient channel of a gradient coil arrangement of the magnetic resonance device. This may also be the subject of the precalculation and/or of the interpolation and/or extrapolation. In general, the present embodiments may use, for the radiofrequency pulses, and, if applicable, also for the gradient pulses, complicated pulse shapes (e.g., if applicable, also transmit k-space trajectories) that allow the total output duration of the drive sequence for use to be kept short (e.g., shorter than 1 ms). The present embodiments relate to parallel transmission (pTx) (e.g., providing the plurality of transmit channels with respective radiofrequency pulses in order to implement a parallel transmission procedure). In one embodiment, the method described here therefore relates to dynamic and/or multi-pulse pTx, in which transmit k-space trajectories are used and, for example, also incorporated in the precalculation (e.g., in the optimization process) for the precalculated drive sequences. The provision method (and also the capture method) may be employed in ultra-high field magnetic resonance imaging (e.g., at main magnetic field strengths of at least 7 Tesla).

In the present embodiments, in the precalculation, the entire conceivable variability of the requirement parameters is deliberately not covered, but only (e.g., a few) reference points are covered for the precalculation. This may then be performed far more quickly. For measurement procedure values that do not correspond to the reference points, an interpolation and/or extrapolation may be performed in order to ascertain nonetheless a drive sequence for use that provides the target excitation state at high quality (e.g., in terms of the spatial selectivity).

In other words, the parameter space of the requirement parameters may be optimized only for specific reference points. Although this takes a relatively long time, it is far less than the months or years mentioned. If then, in an actual examination for a measurement procedure, a measurement procedure value for at least one requirement parameter that lies between the reference points or outside the reference points is required, a drive sequence for use is calculated by interpolation or extrapolation using at least the (e.g., existing) base sequences for the immediately adjacent reference points.

Thus, there are already significant differences from the already known methodologies. For example, in the SmartPulse method, a choice is made only from amongst precalculated universal pulses based on specific attributes/quantities (e.g., localizer data, size, weight, BMI, etc.), but no further interpolation is carried out, which provides that an optimum drive sequence may never be selected because the universal pulses do not include all the parameter combinations. In the case of standardized universal pulses, complex factors are computed for each transmit channel based on a comparison of the B1 maps of the object under examination with reference B1 maps that were used as the basis for the standardized universal pulses. Other parameters beyond the B1 maps are not considered. Therefore, drive sequences that are better matched to the actual requirements are not obtained in this case either. Further, the SmartPulse method and the standardized universal pulses method have been developed so far only for non-selective excitations, which provides that, for example, requirement parameters relating to the target region are not considered.

When a measurement procedure value coincides with a reference point, corresponding base sequences may be used directly as the drive sequences for use (e.g., if measurement procedure values for other requirement parameters do not differ, which would otherwise require interpolation or extrapolation).

In a development of the present embodiments, the target region is a slice. One or more requirement parameters of the at least one requirement parameter are selected from the group including a slice thickness, a slice orientation, and a slice position. Requirement parameters may thus relate, for example, to target regions (e.g., slices). In other words, the present embodiments may provide improved spatially selective excitation. For example, for the slice thickness, the reference points may be defined at a spacing of one millimeter and/or for a parameter interval of 1 to 10 mm, and/or for the slice orientation, the reference points may include an axial, sagittal, and coronal orientation. A corresponding subdivision is also possible for slice positions. The subject of the precalculation for the slice thickness may be, for example, reference points at 1, 2, 3, 4 and 5 mm. If then a drive sequence for use is meant to be ascertained for a slice thickness of 2.5 mm, for example, this is quickly possible by interpolation using at least the base sequences for 2 mm and 3 mm.

Requirement parameters may also relate to other aspects of the target excitation state or of the measurement procedure generally, however. For example, it may be provided that one or more requirement parameters of the at least one requirement parameter are selected from the group including a target flip angle and an energy parameter specifying a desired energy regularization. For example, ten reference points may be selected for (e.g., frequently used) target flip angles, where further target flip angles may be covered by interpolation or extrapolation. The procedure according to the present embodiments may also be extended to deal with SAR by having at least one requirement parameter that is related to energy regularization, which concerns the, if applicable, locally resolved, energy input to the object under examination as a result of achieving the target excitation state. It was previously known in this regard (e.g., in the known standardized universal pulses method) to extend the radiofrequency pulses and/or gradient pulses by a factor, and to reduce the voltages (pulse shapes) by the same factor, when SAR limit values are infringed. In this case, the present embodiments allow SAR problems to be dealt with in a far better manner that is matched to actual circumstances.

The precalculated base sequences are already provided before the imaging takes place at the object under examination. For example, the precalculated base sequences are provided already during the manufacture or in a standard update of the magnetic resonance device.

The base sequences may be ascertained in an optimization process and/or based on reference field distribution maps, including at least one B0 map and at least one B1 map, of a cohort of reference objects under examination. This provides that for ascertaining the base sequences in the precalculation procedure, it is possible to employ, for example, methodologies already proposed for universal pulses and the like, including a, for example, comprehensive optimization. Complicated radiofrequency pulses, and, if applicable, also gradient pulses, are ascertained for a number of optimization parameters in the, for example, comprehensive optimization process. For example, in the optimization process, pulse shapes and/or the timing may also be the subject of the optimization. The precalculations for ascertaining the precalculated drive sequences in optimization processes may be extremely complex and result in extremely complicated pulse shapes that cannot be described easily mathematically and were based on a large number of variables to be optimized. For example, the pulses in the precalculated drive sequences (and also the resultant drive sequences for use) may not be coherent in time and/or space.

It may be provided that a plurality of sets of base sequences, each allocated to one cluster of the cohort, are ascertained and provided. For example, the cohort of reference objects under examination, or respectively the reference field distribution maps, may be divided into classes of comparable cases, known as clusters, with the optimization process being performed separately for the clusters in a way that yields optimum base sequences for the clusters overall. With regard to the interpolation or extrapolation, it may be provided that this is based only on the base sequences of clusters that arise for the current measurement procedure, something that may be deduced from, for example, field distribution maps acquired for the measurement procedure on the object under examination. This is discussed in greater detail below.

In principle, in the context of the present embodiments, traditional interpolation methods and/or extrapolation methods may be used in the derivation algorithm. For example, for this purpose, a model may be defined and/or Bloch simulations may be carried out. It is rather time-consuming, however, to employ the traditional interpolation and/or extrapolation methods, which may use fits, for example. In addition, the interpolation and/or extrapolation problem is in general non-convex, and specifically non-linear.

Therefore, an embodiment provides that the derivation algorithm includes the use of a trained subfunction for performing the interpolation and/or extrapolation. Thus, artificial intelligence (e.g., in the form of a trained neural network) may be employed to perform the interpolation and/or extrapolation. Artificial intelligence is characterized, for example, also by fast calculation times, and therefore, using a trained subfunction is superior in this regard to “traditional” methods that work without artificial intelligence.

In general, a trained function models cognitive functions that humans associate with other human brains. As a result of training based on training data (e.g., machine learning), the trained function is capable of adapting to new circumstances and detecting and extrapolating patterns.

Generally speaking, parameters of a trained function may be adapted by training. For example, supervised learning, semi-supervised learning, unsupervised learning, reinforcement learning, and/or active learning may be used. Further, representation learning (e.g., feature learning) may also be employed. The parameters of the trained function may be adapted, for example, iteratively by a plurality of training steps.

A trained function may include, for example, a neural network, a support vector machine (SVM), a decision tree, and/or a Bayes network, and/or the trained function may be based on k-means clustering, Q-learning, genetic algorithms, and/or association rules. For example, a neural network may be a deep neural network, a convolutional neural network (CNN), or a deep CNN. In addition, the neural network may be an adversarial network, a deep adversarial network, and/or a generative adversarial network (GAN).

In the present case, it may be advantageous that the subfunction includes a CNN (e.g., a U-net). This has been shown to have particularly positive results.

It may be intended that the subfunction is provided as the result of a training procedure in which the subfunction is trained based on ground truths obtained in a precalculation process also used for the base sequences. It may be provided, for example, that additional values of the requirement parameter that lie between reference points are precalculated (e.g., simulated) in order to ascertain ground truths for training datasets. In one embodiment, however, reference-point base sequences may (e.g., additionally) be assumed to be unknown, so to be found as a ground truth, and the reference-point base sequences may interpolated/extrapolated from the other base sequences.

The training procedure may be performed separately for at least one reference set of reference field distribution maps. The reference set may contain field distribution maps that are representative of a cluster. If the training relates to a specific reference set of reference field distribution maps, this rules out any variability regarding these maps, and therefore, it is possible to complete optimization processes more quickly for ascertaining base sequences and/or ground truths (e.g., at values of the at least one requirement parameter that is to be interpolated/extrapolated). Based on this, the training then takes place. For example, field distribution maps that are representative of a cluster may be used in order to ascertain additional ground truths for the training for clusters for which the base sequences already exist.

In one embodiment, field distribution maps including a B0 map and at least one B1 map and captured at the object under examination may be provided, and the derivation algorithm may use the field distribution maps in addition to the measurement procedure value as input data. The required field distribution maps may be acquired using the magnetic resonance device itself (e.g., with an acquisition duration of a few tens of seconds, such as 30 to 60 seconds). The field distribution maps allow the attributes of the object under examination to be taken into account. B1 maps each describe the spatial B1 field distribution for a specific transmit coil of the transmit coil arrangement (e.g., for a specific transmit channel of the radiofrequency coil arrangement). In other words, the B1 maps describe the spatial sensitivity of the corresponding transmit coil. B0 maps describe, in a spatially resolved manner, the deviations of the main magnetic field (e.g., B0 field) from the actually desired homogeneous field profile, and hence the local deviation of the Larmor frequency from the desired (nominal) Larmor frequency.

In the present embodiments, field distribution maps may be used for a plurality of different purposes. For example, it may be provided that as part of the derivation algorithm, the field distribution maps are used as the starting point for allocation to a cluster and for selecting the base sequences allocated to the cluster. Artificial intelligence may also be employed for the allocation to a cluster (e.g., in the form of a trained cluster-identification function).

It may also be provided, for example, that the trained subfunction also uses the field distribution maps as input data. This may be provided, for example, when the examinations associated with new measurement procedure values also involve field distribution maps that have greater variation, possibly even within a cluster. Thus, changes in the B0 and/or B1 field distribution arising from the different value of the requirement parameter (e.g., with regard to the target region) may also be taken into account (e.g., in the case of extensions relating to large “slabs”).

In a development of the present embodiments, it may be provided that the derivation algorithm has an act that comes after the interpolation and/or extrapolation, for optimizing the therein-derived drive sequence for use for optimally achieving the target excitation state, taking into account the field distribution maps in at least one optimization procedure. Approaches such as those in the FOCUS method may be used here, for example, in which the interpolated and/or extrapolated drive sequence is ultimately used as the starting point for a further optimization based on the current field distribution maps. In this case, the interpolation and/or extrapolation delivers what are effectively starting values, in order to achieve a further improvement through an optimization procedure. For example, being certain that the starting point for the optimization procedure is excellent, a Bloch simulation may be used to make a comparison with the target excitation state, and based on the result, an improvement may be made in an optimization algorithm (e.g., a gradient descent method) by adjusting a specific set of optimization parameters. Target functions may, for example, relate to the degree to which the target excitation state is reached and/or to the energy input to the object under examination, where these aspects may also be covered by boundary conditions. Further boundary conditions may relate to the performance and/or power rating of the magnetic resonance device or of its relevant components.

Although the base sequences have been ascertained in an optimization process based on relevant field distribution maps, deviations from the optimum may still arise as a result of the interpolation and/or extrapolation, and therefore, an improvement in quality may be achieved by an additional “traditional” optimization procedure such as this, which comes after the interpolation/extrapolation. This also increases the reliability and robustness of the drive sequence for use.

In a method according to the present embodiments for capturing measurement data from an object under examination using a magnetic resonance device, it is provided that a drive sequence for use is provided using a computer-implemented provision method according to the present embodiments, and in the capture procedure, the radiofrequency pulses of the drive sequence for use are output by the radiofrequency coil arrangement in order to produce the target excitation state. If the drive sequence for use is ascertained also including gradient pulses, the gradient pulses are accordingly output via gradient coils of a gradient coil arrangement of the magnetic resonance device. All the statements relating to the computer-implemented provision method may be applied analogously to the capture method according to the present embodiments, and therefore, the advantages already described may also be achieved by this method. For example, by virtue of it quickly providing the drive sequence for use, the capture method according to the present embodiments may be used in the clinical field (e.g., for medical imaging) in order to obtain high quality measurement data and hence, for example, also magnetic resonance image datasets (e.g., when drive sequences are needed that have a short total output duration, such as in the case of gradient echo sequences).

As already mentioned, it may be provided that the field distribution maps are acquired using the magnetic resonance device before the drive sequence for use is provided. Appropriate fast magnetic resonance sequences (e.g., executable in less than a minute) have already been proposed in the prior art. Alternatively, measuring probes or the like may, for example, be used to measure the field distribution maps.

The present embodiments also relate to a provision and/or acquisition system having a computing device. The computing device may be configured both to perform a provision method according to the present embodiments and to perform a capture method according to the present embodiments. For example, in the case of an acquisition system, this may also include a magnetic resonance device having a radiofrequency coil arrangement and a control device that may form part of the computing device. For example, the magnetic resonance device may also have a gradient coil arrangement for the output of gradient pulses and/or have a main magnetic field strength of at least 7 Tesla (e.g., be configured for ultra-high field magnetic resonance imaging).

For example, in the case of a provision system, this (e.g., the computing device) may also include an optimization device (e.g., in a computing center). The optimization device may be configured to precalculate the base sequences. The base sequences may then be provided to the magnetic resonance device (e.g., during or after its production and/or in an update). The control device of the magnetic resonance device may have, in addition to a storage means (e.g., a storage device) for the base sequences amongst other things, an interface for receiving the measurement procedure value for the at least one requirement parameter, and a derivation unit for executing the derivation algorithm. For the capture method, the control device may also have a sequence unit that generally controls the acquisition operation of the magnetic resonance device, and hence is configured, for example, to control the capture procedure and, if applicable, the acquisition of the field distribution maps. In addition, further functional units may be provided for implementing developments of the methods according to the present embodiments. All the statements relating to the methods according to the present embodiments may be applied analogously to the provision and/or acquisition system according to the present embodiments, and therefore, the advantages already described may also be achieved by this system.

A computer program according to the present embodiments may be loaded directly into a storage means (e.g., storage device) of a computing device, and includes program means that cause the computing device to perform the acts of a method according to the present embodiments when the computer program is executed. The computer program may be stored on an electronically readable data storage medium according to the present embodiments, which therefore includes control information stored thereon that includes at least one computer program according to the present embodiments and is configured such that when the data storage medium is used in a computing device, this device is designed to perform a method according to the present embodiments. In an implementation of the capture method as a computer program, for the purpose of capturing measurement data and/or field distribution maps, a control device of the computing device is caused to drive accordingly further components of a magnetic resonance device (e.g., the radiofrequency coil arrangement and the gradient coil arrangement).

### BRIEF DESCRIPTION OF THE DRAWINGS

FIG. 1 shows an example embodiment of an artificial neural network;

FIG. 2 shows an example embodiment of a convolutional neural network;

FIG. 3 is a flowchart of an example embodiment of a capture method;

FIG. 4 is a schematic diagram for the provision of base functions for reference points, and use of the base functions for interpolation and/or extrapolation; and

FIG. 5 is a schematic diagram of a provision and acquisition system according to an embodiment.

### DETAILED DESCRIPTION

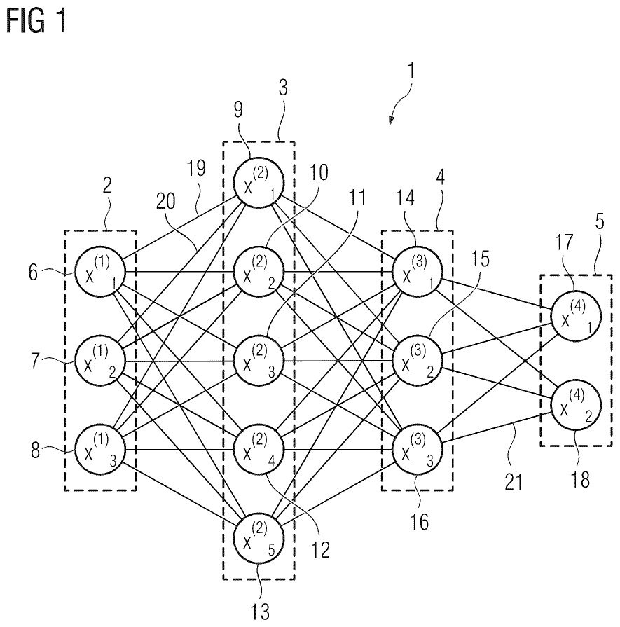

FIG. 1 shows an example embodiment of an artificial neural network 1. Other terms used for the artificial neural network 1 are neural network, artificial neural net, or neural net.

The artificial neural network 1 includes nodes 6 to 18 and edges 19 to 21, where each edge 19 to 21 is a directed connection of a first node 6 to 18 to a second node 6 to 18. In general, the first node 6 to 18 and the second node 6 to 18 are different nodes 6 to 18; in one embodiment, however, the first node 6 to 18 and the second node 6 to 18 are the same. For example, in FIG. 1, the edge 19 is a directed connection from the node 6 to the node 9, and the edge 21 is a directed connection from the node 16 to the node 18. An edge 19 to 21 from a first node 6 to 18 to a second node 6 to 18 is referred to as an ingoing edge for the second node 6 to 18, and as an outgoing edge for the first node 6 to 18.

In this example embodiment, the nodes 6 to 18 of the artificial neural network 1 may be arranged in layers 2 to 5, where the layers may have an intrinsic order instituted by the edges 19 to 21 between the nodes 6 to 18. For example, edges 19 to 21 may be provided only between adjacent layers of nodes 6 to 18. In the example embodiment shown, there is an input layer 2 that has only the nodes 6, 7, 8, none having an ingoing edge. The output layer 5 includes only the nodes 17, 18, neither having outgoing edges, with hidden layers 3 and 4 additionally lying between the input layer 2 and the output layer 5. In the general case, any number of hidden layers 3, 4 may be chosen. The number of nodes 6, 7, 8 in the input layer 2 may equal the number of input values to the neural network 1, and the number of nodes 17, 18 in the output layer 5 may equal the number of output values from the neural network 1.

For example, a number (e.g., real number) may be assigned to the nodes 6 to 18 of the neural network 1. Here, x⁽ⁿ⁾ᵢ denotes the value of the i-th node 6 to 18 of the n-th layer 2 to 5. The values of the nodes 6, 7, 8 in the input layer 2 are equal to the input values of the neural network 1, whereas the values of the nodes 17, 18 in the output layer 5 are equal to the output values of the neural network 1. Further, each edge 19, 20, 21 may be assigned a weight in the form of a real number. For example, the weight is a real number in the interval [−1, 1] or in the interval [0, 1,]. Here, w^{(m,n)}_{i,j} denotes the weight of the edge between the i-th nodes 6 to 18 of the m-th layer 2 to 5 and the j-th nodes 6 to 18 of the n-th layer 2 to 5. In addition, the abbreviation w is defined for the weight w_{i,j}^{(n,n+1)}.

The input values are propagated through the neural network 1 in order to calculate output values of the neural network 1. For example, the values of the nodes 6 to 18 of the (n+1)-th layer 2 to 5 may be calculated based on the values of the nodes 6 to 18 of the n-th layer 2 to 5 by

$${x}_{j}^{( n + 1 )} = f ( {\sum }_{i} {x}_{i}^{( n )} \cdot {w}_{i , j}^{( n )} ) .$$

Here, f is a transfer function that may also be referred to as an activation function. Known transfer functions are step functions, sigmoid functions (e.g., the logistic function, the generalized logistic function, the hyperbolic tangent, the arc tangent, the error function, the smooth-step function), or rectifier functions. The transfer function is used essentially for normalization purposes.

For example, the values are propagated layer by layer through the neural network 1, with values in the input layer 2 being given by the input data to the neural network 1. Values in the first hidden layer 3 may be calculated based on the values in the input layer 2 of the neural network 1; values of the second hidden layer 4 may be calculated based on the values in the first hidden layer 3, and so on.

The neural network 1 is to be trained using training data in order to be able to establish the values w for the edges 19 to 21. For example, training data includes training input data and training output data that is referred to below as ti. For a training step, the neural network 1 is applied to the training input data in order to obtain calculated output data. For example, the training output data and the calculated output data include a number of values, where the number is determined as the number of nodes 17, 18 in the output layer 5.

For example, a comparison between the calculated output data and the training output data is used to adjust the weights within the neural network 1 recursively (e.g., backpropagation algorithm). For example, the weights may be modified according to

$${w}_{i , j}^{′ ( n )} = {w}_{i , j}^{( n )} - γ \cdot {δ}_{j}^{( n )} \cdot {x}_{i}^{( n )}$$

where y is a learning rate, and the numbers δⱼ⁽ⁿ⁾ may be calculated recursively as

$${δ}_{j}^{( n )} = ( {\sum }_{k} {δ}_{k}^{( n + 1 )} \cdot {w}_{j , k}^{( n + 1 )} ) \cdot {f}^{′} ( {\sum }_{i} {x}_{i}^{( n )} \cdot {w}_{i , j}^{( n )} )$$

based on δⱼ⁽ⁿ⁺¹⁾ if the (n+1)-th layer is not the output layer 5, and as

$${δ}_{j}^{( n )} = ( {x}_{k}^{( n + 1 )} - {t}_{j}^{( n + 1 )} ) \cdot {f}^{′} ( {\sum }_{i} {x}_{i}^{( n )} \cdot {w}_{i , j}^{( n )} )$$

if the (n+1)-th layer is the output layer 5, where f is the first derivative of the activation function, and yⱼ⁽ⁿ⁺¹⁾ is the comparison training value for the j-th node 17, 18 in the output layer 5.

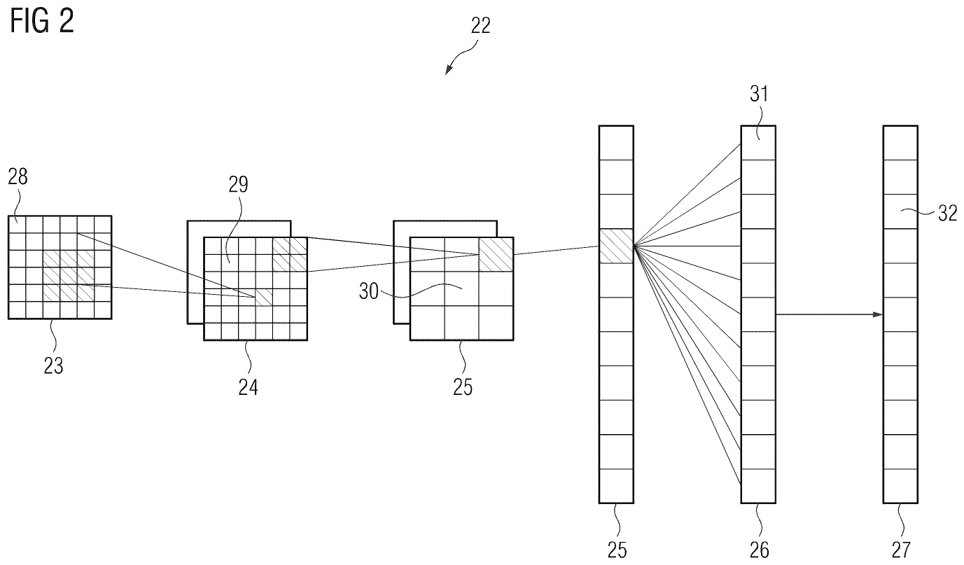

An example of a convolutional neural network (CNN) is given below with reference to FIG. 2. The term “layer” is used in this context in a slightly different way than for classical neural networks. For a classical neural network, the term “layer” refers just to the set of nodes that forms a layer (e.g., a particular generation of nodes). For a convolutional neural network, the term “layer” is often used as an object that actively changes data (e.g., as a set of nodes of the same generation and either the set of ingoing edges or of outgoing edges).

FIG. 2 shows an example embodiment of a convolutional neural network 22. In the example embodiment shown, the convolutional neural network 22 includes an input layer 23, a convolutional layer 24, a pooling layer 25, a fully connected layer 26, and an output layer 27. In alternative embodiments, the convolutional neural network 22 may contain a plurality of convolutional layers 24, a plurality of pooling layers 25, and a plurality of fully connected layers 26, just like other types of layers. The layers may be chosen to have any order, although fully connected layers 26 may form the last layers before the output layer 27.

For example, within a convolutional neural network 22, the nodes 28 to 32 in one of the layers 23 to 27 may be considered to be arranged in a d-dimensional matrix or as a d-dimensional image. For example, in the two-dimensional case, the value of a node 28 to 32 with indices i, j in the n-th layer 23 to 27 may be denoted by x⁽ⁿ⁾[i,j]. The arrangement of the nodes 28 to 31 in a layer 23 to 27 has no effect whatsoever on the calculations inside the convolutional neural network 22 as such, because these effects are given solely by the structure and weights of the edges.

A convolutional layer 24 is characterized, for example, in that the structure and the weights of the ingoing edges form a convolution operation based on a certain number of kernels. For example, the structure and the weights of the ingoing edges may be selected such that the values xₖ⁽ⁿ⁾ of the nodes 29 of the convolutional layer 24 are determined as a convolution xₖ⁽ⁿ⁾=Kₖ*x⁽ⁿ⁻¹⁾ based on the values x⁽ⁿ⁻¹⁾ of the nodes 28 in the previous layer 23, where the convolution * in the two-dimensional case can be defined as

$${x}_{k}^{( n )} [ i , j ] = ( {K}_{k} * {x}^{( n - 1 )} ) [ i , j ] = {\sum }_{{i}^{′}} {\sum }_{{j}^{′}} {K}_{k} [ {i}^{′} , {j}^{′} ] \cdot {x}^{( n - 1 )} [ i - {i}^{′} , j - {j}^{′} ] .$$

Here, the k-th kernel Kₖ is a d-dimensional matrix (e.g., in the example embodiment, a two-dimensional matrix), which is usually small in comparison with the number of nodes 28 to 32 (e.g., a 3×3 matrix or a 5×5 matrix). The implication of this, for example, is that the weights of the ingoing edges are not independent but are selected such that the weights create the above convolution equation. In the example of a kernel that forms a 3×3 matrix, there are just nine independent weights (e.g., where each entry in the kernel matrix corresponds to an independent weight), irrespective of the number of nodes 28 to 32 in the associated layer 23 to 27. For example, for a convolutional layer 24, the number of nodes 29 in the convolutional layer 24 is equal to the number of nodes 28 in the previous layer 23 multiplied by the number of convolution kernels.

If the nodes 28 in the previous layer 23 are arranged as a d-dimensional matrix, using the plurality of kernels may be interpreted as adding a further dimension, also referred to as the depth dimension, with the result that the nodes 29 of the convolutional layer 24 are arranged as a (d+1)-dimensional matrix. If the nodes 28 in the previous layer 23 are already arranged as a (d+1)-dimensional matrix having a depth dimension, using a plurality of convolution kernels may be interpreted as an expansion along the depth dimension, resulting in the nodes 29 of the convolutional layer 24 being arranged likewise as a (d+1)-dimensional matrix, but with the size of the (d+1)-dimensional matrix in the depth dimension being larger than in the previous layer 23 by the factor given by the number of kernels.

The advantage of using convolutional layers 24 is that the spatially local correlation in the input data may be exploited by creating a local connection pattern between nodes in neighboring layers (e.g., by each node having connections just to a small region of the nodes in the previous layer).

In the example embodiment shown, the input layer 23 includes thirty-six nodes 28 that are arranged as a two-dimensional 6×6 matrix. The convolutional layer 24 includes seventy-two nodes 29 that are arranged as two two-dimensional 6×6 matrices, with each of the two matrices being the result of convolving the values in the input layer 23 with a convolution kernel. Equally, the nodes 29 of the convolutional layer 24 may be considered to be arranged in a three-dimensional 6×6×2 matrix, where the last dimension is the depth dimension.

A pooling layer 25 is characterized in that the structure and the weights of the ingoing edges, and the activation function of its nodes 30, define a pooling operation based on a non-linear pooling function f. For example, in the two-dimensional case, the values x⁽ⁿ⁾ of the nodes 30 in the pooling layer 25 are calculated based on the values x⁽ⁿ⁺¹⁾ of the nodes 29 in the previous layer 24 as

$${x}^{( n )} [ i , j ] = f ( {x}^{( n - 1 )} [ {id}_{1} , {jd}_{2} ] , … , {x}^{( n - 1 )} [ {id}_{1} + {d}_{1} - 1 , {jd}_{2} + {d}_{2} - 1 ] )$$

In other words, using a pooling layer 25 may reduce the number of nodes 29, 30 by replacing a plurality of d₁×d₂ adjacent nodes 29 in the previous layer 24 with a single node 30 that is calculated as a function of the values of the plurality of adjacent nodes 29. For example, the pooling function f may be a maximum function, an averaging, or the L2 norm. For example, the weights of the ingoing edges may be fixed for a pooling layer 25 and not modified by training.

The advantage of using a pooling layer 25 is that the number of nodes 29, 30 and the number of parameters is reduced. This leads to a reduction in the amount of calculations required inside the convolutional neural network 22 and hence to control of overfitting.

In the example embodiment shown, the pooling layer 25 is a max pooling layer, in which four adjacent nodes are replaced by just a single node that has a value formed by the maximum of the values of the four adjacent nodes. The max pooling is applied to each d-dimensional matrix of the previous layer; in this example embodiment, the max pooling is applied to each of the two two-dimensional matrices, resulting in a reduction in the number of nodes from seventy-two to eighteen.

A fully connected layer 26 is characterized in that a plurality of (e.g., all) edges between the nodes 30 in the previous layer 25 and the nodes 31 in the fully connected layer 26 are present, and the weight of each of the edges may be adjusted individually. In this example embodiment, the nodes 30 in the previous layer 25 and in the fully connected layer 26 are shown both as two-dimensional matrices and as non-related nodes (e.g., represented as a row of nodes, where the number of nodes has been reduced for better visualization). In this example embodiment, the number of nodes 31 in the fully connected layer 26 equals the number of nodes 30 in the previous layer 25. In alternative embodiments, the number of nodes 30, 31 may be different.

Further, in this example embodiment, the values of the nodes 32 in the output layer 27 are determined by applying the softmax function to the values of the nodes 31 in the previous layer 26. By applying the softmax function, the sum of the values of all the nodes 32 in the output layer 27 equals one, and all the values of all the nodes 32 in the output layer are real numbers between 0 and 1. If the convolutional neural network 22 is used for classifying input data, then, for example, the values of the output layer 27 may be interpreted as a probability that the input data falls into one of the different classes.

A convolutional neural network 22 may likewise have a ReLU layer, where ReLU is an acronym for “rectified linear units”. For example, the number of nodes and the structure of the nodes within a ReLU layer is equivalent to the number of nodes and the structures of the nodes in the previous layer. The value of each node in the ReLU layer may be calculated, for example, by applying a rectifier function to the value of the corresponding node in the previous layer. Examples of rectifier functions are f(x)=max(0,x), the hyperbolic tangent, or the sigmoid function.

Convolutional neural networks 22 may be trained, for example, based on the backpropagation algorithm. Regularization methods may be employed in order to avoid overfitting (e.g., methods such as dropout of individual nodes 28 to 32, stochastic pooling, use of artificial data, weight decay based on the L1 or L2 norm, or max norm constraints).

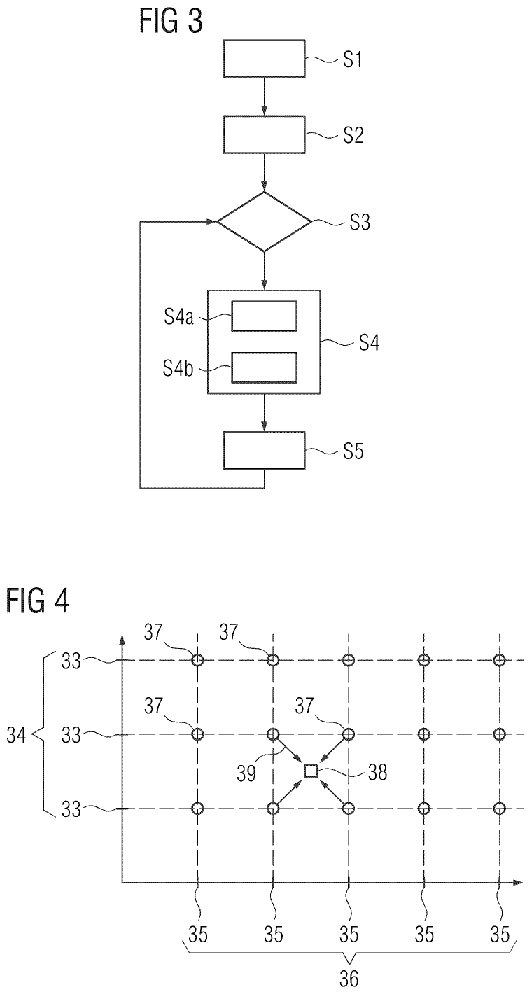

FIG. 3 shows a flowchart of an example embodiment of a capture method according to the present embodiments, which includes a provision method according to the present embodiments.

The provision method serves to provide a drive sequence for use for producing a target excitation state for a procedure for capturing measurement data from an object under examination using a magnetic resonance device. The procedure is then carried out as part of the capture method. The magnetic resonance device has a main magnet that generates a main magnetic field (e.g., B0 field) at a main field strength of 7 Tesla or more. A radiofrequency coil arrangement of the magnetic resonance device has a plurality of radiofrequency coils that may be driven via respective transmit channels in order to excite nuclear spins of the object under examination to generate the target excitation state. In addition, a gradient coil arrangement is provided, which has a plurality of gradient coils (e.g., three), each of which is associated with one of the Cartesian spatial directions (X, Y, Z) of the magnetic resonance device. The gradient coils may be driven via respective gradient channels to output gradient pulses.

In order to produce the target excitation state, it is intended here to employ dynamic parallel transmission, and therefore, the drive sequence includes both gradient pulses (e.g., for implementing a transmit k-space trajectory) and radiofrequency pulses for the transmit channels. These all have highly complicated pulse shapes. In addition, a plurality of radiofrequency pulses may be used per transmit channel (multi-pulse pTx).

In the present case, the target excitation state intends spatially selective excitation, which provides that a homogeneous flip-angle distribution is only intended to be produced in a target region (e.g., a slice in this case); other nuclear spins of the object under examination are not meant to be excited. The slice is defined, for example, by a plurality of requirement parameters, specifically the slice thickness, the orientation of the slice, and the slice position (e.g., defined by the position of the central point of the slice). It is also possible to use other requirement parameters relating to the target excitation state (e.g., the flip angle to be attained), however, and at least one energy parameter relating to energy regularization. The energy parameter is intended to limit energy inputs that are relevant to the SAR exposure of the object under examination (e.g., of a patient).

In order to find an optimum drive sequence for use for such measurement procedures and target excitation states, preparation is first needed, as given by act S1. In this act, optimization is used in optimization processes to precalculate base sequences, based on which the drive sequence for use is to be ascertained for the later actual cases of use. These base sequences are not determined for all conceivable values of the requirement parameters, however, but only for some reference points. For example, with regard to the slice thickness, reference points may be used at 1 mm, 2 mm, 3 mm, 4 mm, and 5 mm in order to cover a parameter interval of 1 to 5 mm or even larger (e.g., from 0.5 to 5.5 mm) when extrapolation is conceivable. With regard to the slice orientation, three reference points may be used, specifically the mainly used coronal orientation, the sagittal orientation, and the axial orientation, whereas similar reference points to those for the slice thickness are used for the slice position (e.g., on a grid). 27 reference points may be used, for example. As regards the flip angle, 10 reference points may be used, for example.

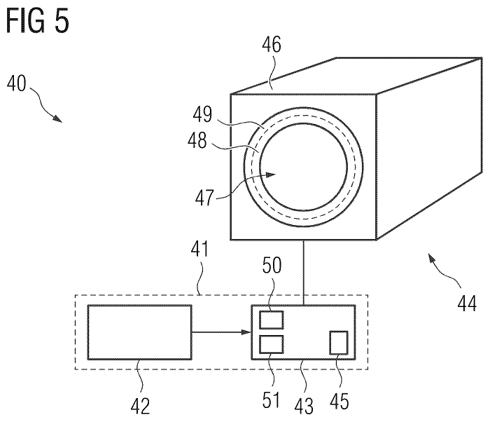

This is shown schematically in FIG. 4 for two requirement parameters (e.g., for the orientation of the slice having the three reference points 33 in the parameter interval 34, and for the slice thickness having the five reference points 35 in the parameter interval 36). Optimization processes that may be performed as generally known in the prior art may precalculate base sequences 37, which are also indicated in FIG. 4, for each of the reference points. The parameter space for the requirement parameters is hence covered by discrete points (e.g., in the form of a grid).

The optimization processes are based, for example, on field distribution maps (e.g., B0 maps and B1 maps) for a cohort of objects under examination, based on which the optimization is performed. The objects under examination, or their field distribution maps, are grouped into clusters, for example, as is generally known, so that sets of base sequences 37 (e.g., for the different reference points 33, 35) are precalculated for each cluster. Each cluster may also be allocated a representative set of B0 map and B1 maps. The optimization process then aims to achieve the target excitation state as precisely as possible for all the field distribution maps of the cluster. For this purpose, magnetizations may be ascertained (e.g., by Bloch simulations) for test sets of the optimization parameters and compared with the magnetization defined by the target excitation state, and the test set may be adjusted based on this comparison. Boundary conditions may again relate, for example, to SAR and to the performance and the power rating of the magnetic resonance device.

In act S2, (see FIG. 3), the precalculated base sequences 37 are provided at the magnetic resonance device. For example, the precalculated base sequences 37 are stored after production or during an update in a storage means (e.g., a storage device) of a control device of the magnetic resonance device.

For measurement procedures, requirement parameters are then provided during usual operation of the magnetic resonance device (e.g., as a result of a user input and/or by an information system, such as a radiology information system, and/or on based on a selection of an acquisition program at the magnetic resonance device). In act S3, it is therefore checked whether a measurement procedure containing associated measurement procedure values of the requirement parameters is present. If this is the case, a derivation algorithm for ascertaining the drive sequence for use is executed in act S4.

If clusters are used, then initially, by analyzing current field distribution maps acquired for the current object under examination using the magnetic resonance device, a current cluster may be ascertained (e.g., by a trained cluster identification function, as is generally known in the prior art). Only the base functions 37 that are allocated to this current cluster are used subsequently.

The derivation algorithm has two subacts in the present case, specifically the act S4a and the act S4b. In the act S4a, a trained subfunction, which includes a CNN 22, is executed in order to derive the drive sequence 38 for use from the base sequences 37, if necessary, by interpolation, as is also shown schematically in FIG. 4. The requirement parameters for the orientation and the slice thickness, for example, each lie between two of the reference points 33, 35, which provides that interpolation is necessary, at least for these two requirement parameters. If the measurement procedure value of a requirement parameter corresponds to one of the reference points 33, 35, then no interpolation is needed in this case. The interpolation incorporates at least the base sequences 37 of the immediately adjacent reference points 33, 35, as indicated by the arrows 39 in FIG. 4.

The trained subfunction is provided after a training procedure has been carried out. Training datasets may be provided for this training procedure in different ways; one way is by further optimization processes for values of the requirement parameters 33, 35 that lie between the reference points 33, 35, whereas another way is to regard the base sequences 37 for specific reference points 33, 35 as ground truths that shall be derived from adjacent base sequences 37. For further optimization processes, only the representative set of B0 map and B1 field maps are used here as the reference set for each cluster in order to provide simplification.

In one embodiment, the field distribution maps are also presented as input data during the subfunction training procedure. During its subsequent use, the trained subfunction again uses the field distribution maps of the current object under examination as input data. This allows deviations (e.g., also within clusters) to be taken into account as well.

In a subact S4b, the drive sequence for use derived in subact S4a is optimized further again in an optimization procedure using the field distribution maps of the current object under examination, and is hence adjusted to better fit the current actual acquisition situation. Techniques such as those in the FOCUS method may be applied here, for example; otherwise, for example, also for a reduced number of optimization parameters, standard optimization algorithms for achieving the target magnetization as precisely as possible may be executed. For example, a target function may be employed that minimizes a measure of the deviation of a magnetization that has been obtained using a test set of optimization parameters in a Bloch simulation, from the target magnetization given by the target excitation state. Boundary conditions may relate to the energy input to the object under examination (e.g., SAR considerations) and to the performance and/or power rating of the magnetic resonance device. New test sets may be ascertained, for example, based on a gradient descent method.

In act S5, the optimized drive sequence for use is then used to perform the measurement procedure with the magnetic resonance device in order to capture measurement data, from which a magnetic resonance image dataset, for example, may be ascertained. For this purpose, the radiofrequency pulses are output by the radiofrequency coil arrangement, and the gradient pulses are output by the gradient coil arrangement.

FIG. 5 shows a schematic diagram of a provision and acquisition system 40 according to the present embodiments. This includes, first, a computing device 41 that is configured to perform the method according to the present embodiments and here consists of two main components, specifically an optimization device 42 that may be part of a computing center, for example, and has a high computing power, and the control device 43 of a magnetic resonance device 44, which also forms part of the provision and acquisition system 40.

The optimization device 42 is configured to precalculate the base sequences 37 (cf., act S1), which are then provided to the control device 43 via a suitable interface (cf., step S2). In the control device 43, the base sequences 37 may be stored in a storage means 45 (e.g., a storage device).

The magnetic resonance device 44 includes, as is generally known, a main magnetic unit 46 that includes the superconducting main magnet (not shown in detail here) for generating the main magnetic field at the main magnetic field strength of at least 7 Tesla. The main magnetic unit 46 defines a cylindrical patient placement area 47, into which a patient may be moved by a patient couch (not presented here in greater detail). The patient placement area 47 is surrounded, for example, by a gradient coil arrangement 48 and a radiofrequency coil arrangement 49, where the, or a further, radiofrequency coil arrangement 49 may also be implemented as a local coil arrangement.

The gradient coil arrangement 48 includes gradient coils that may be driven via respective gradient channels, whereas the radiofrequency coil arrangement 49 includes transmit coils that may be driven via respective transmit channels. The control device 43 controls the operation of the magnetic resonance device 44.

The acquisition operation of the magnetic resonance device 44 is controlled, for example, via the control unit 50 of the control device 43, which may thus also control the acquisition of the field distribution maps and of the measurement data in act S5. In a derivation unit 51, the derivation algorithm may be executed in accordance with act S4.

Although the present embodiments have been illustrated and described in detail using the example embodiments, the invention is not limited by the disclosed examples, and a person skilled in the art may derive other variations therefrom without departing from the scope of protection of the invention.

Independent of the grammatical term usage, individuals with male, female or other gender identities are included within the term.

The elements and features recited in the appended claims may be combined in different ways to produce new claims that likewise fall within the scope of the present invention. Thus, whereas the dependent claims appended below depend from only a single independent or dependent claim, it is to be understood that these dependent claims may, alternatively, be made to depend in the alternative from any preceding or following claim, whether independent or dependent. Such new combinations are to be understood as forming a part of the present specification.

While the present invention has been described above by reference to various embodiments, it should be understood that many changes and modifications can be made to the described embodiments. It is therefore intended that the foregoing description be regarded as illustrative rather than limiting, and that it be understood that all equivalents and/or combinations of embodiments are intended to be included in this description.

1. A computer-implemented method for providing a drive sequence for use that is target-region selective, for producing a target excitation state for a process for capturing measurement data from an object under examination using a magnetic resonance device, wherein the drive sequence comprises radiofrequency pulses to be output via transmit channels of a radiofrequency coil arrangement, the method comprising:
before an examination comprising a measurement procedure, precalculating a set of base sequences for mutually spaced reference points of at least one requirement parameter that describes the target excitation state, the reference points covering a parameter interval for use, and providing the set of base sequences together with the associated reference points at the magnetic resonance device;
providing a measurement procedure value of the at least one requirement parameter at the magnetic resonance device; and
ascertaining a drive sequence for use for the measurement procedure, wherein when the measurement procedure value for the at least one requirement parameter differs from the reference points, the drive sequence is ascertained from the set of base sequences by interpolation, extrapolation, or interpolation and extrapolation using a derivation algorithm.

2. The method of claim 1, wherein the target region is a slice, wherein the at least one requirement parameter comprises a slice thickness, a slice orientation, a slice position, or any combination thereof.

3. The method of claim 1, wherein the at least one requirement parameter comprises a target flip angle, an energy parameter specifying a desired energy regularization, or the target flip angle and the energy parameter.

4. The method of claim 1, wherein the set of base sequences are ascertained in an optimization process, based on reference field distribution maps of a cohort of reference objects under examination, or in the optimization process and based on the reference field distribution maps, the reference field distribution maps comprising at least one B0 map and at least one B1 map.

5. The method of claim 4, wherein a plurality of sets of base sequences, each allocated to one cluster of the cohort, are ascertained and provided, the plurality of sets of base sequences comprising the set of base sequences.

6. The method of claim 1, wherein the derivation algorithm comprises the use of a trained subfunction for performing the interpolation, the extrapolation, or the interpolation and the extrapolation.

7. The method of claim 6, wherein the subfunction comprises a convolutional neural network (CNN).

8. The method of claim 7, wherein the CNN is a U-net.

9. The method of claim 6, wherein the subfunction is provided as the result of a training procedure in which the subfunction is trained based on ground truths obtained in a precalculation process also used for the set of base sequences.

10. The method of claim 9, wherein the training procedure is performed separately for at least one reference set of reference field distribution maps.

11. The method of claim 1, wherein field distribution maps comprising a B0 map and at least one B1 map and captured at the object under examination are provided, and the derivation algorithm uses the field distribution maps in addition to the measurement procedure value as input data.

12. The method of claim 11, wherein the derivation algorithm comprises, after the interpolation, the extrapolation, or the interpolation and the extrapolation, optimizing the ascertained drive sequence for use for optimally achieving the target excitation state, taking into account the field distribution maps in at least one optimization procedure.

13. A method for capturing measurement data from an object under examination using a magnetic resonance device, the method comprising:
providing a drive sequence for use that is target-region selective, for producing a target excitation state for a process for capturing measurement data from an object under examination using a magnetic resonance device, wherein the drive sequence comprises radiofrequency pulses to be output via transmit channels of a radiofrequency coil arrangement, the providing of the drive sequence comprising:
before an examination comprising a measurement procedure, precalculating a set of base sequences for mutually spaced reference points of at least one requirement parameter that describes the target excitation state, the reference points covering a parameter interval for use, and providing the set of base sequences together with the associated reference points at the magnetic resonance device;
providing a measurement procedure value of the at least one requirement parameter at the magnetic resonance device; and
ascertaining a drive sequence for use for the measurement procedure, wherein when the measurement procedure value for the at least one requirement parameter differs from the reference points, the drive sequence is ascertained from the set of base sequences by interpolation, extrapolation, or interpolation and extrapolation using a derivation algorithm; and
executing the measurement procedure, the executing of the measurement procedure comprising outputting, by the radiofrequency coil arrangement, the radiofrequency pulses of the drive sequence, such that the target excitation state is produced.

14. A provision, acquisition, or provision and acquisition system comprising:
a processor configured to:
provide a drive sequence for use that is target-region selective, for producing a target excitation state for a process for capturing measurement data from an object under examination using a magnetic resonance device, wherein the drive sequence comprises radiofrequency pulses to be output via transmit channels of a radiofrequency coil arrangement, the processor being configured to provide the drive sequence comprising the processor being configured to:
before an examination comprising a measurement procedure, precalculate a set of base sequences for mutually spaced reference points of at least one requirement parameter that describes the target excitation state, the reference points covering a parameter interval for use, and provide the set of base sequences together with the associated reference points at the magnetic resonance device;
provide a measurement procedure value of the at least one requirement parameter at the magnetic resonance device; and
ascertain a drive sequence for use for the measurement procedure, wherein when the measurement procedure value for the at least one requirement parameter differs from the reference points, the drive sequence is ascertained from the set of base sequences by interpolation, extrapolation, or interpolation and extrapolation using a derivation algorithm.

15. In a non-transitory computer-readable storage medium that stores instruction executable by one or more processors to provide a drive sequence for use that is target-region selective, for producing a target excitation state for a process for capturing measurement data from an object under examination using a magnetic resonance device, wherein the drive sequence comprises radiofrequency pulses to be output via transmit channels of a radiofrequency coil arrangement, the instructions comprising:
before an examination comprising a measurement procedure, precalculating a set of base sequences for mutually spaced reference points of at least one requirement parameter that describes the target excitation state, the reference points covering a parameter interval for use, and providing the set of base sequences together with the associated reference points at the magnetic resonance device;
providing a measurement procedure value of the at least one requirement parameter at the magnetic resonance device; and
ascertaining a drive sequence for use for the measurement procedure, wherein when the measurement procedure value for the at least one requirement parameter differs from the reference points, the drive sequence is ascertained from the set of base sequences by interpolation, extrapolation, or interpolation and extrapolation using a derivation algorithm.

16. The non-transitory computer-readable storage medium of claim 15, wherein the target region is a slice, wherein the at least one requirement parameter comprises a slice thickness, a slice orientation, a slice position, or any combination thereof.

17. The non-transitory computer-readable storage medium of claim 15, wherein the at least one requirement parameter comprises a target flip angle, an energy parameter specifying a desired energy regularization, or the target flip angle and the energy parameter.

18. The non-transitory computer-readable storage medium of claim 15, wherein the set of base sequences are ascertained in an optimization process, based on reference field distribution maps of a cohort of reference objects under examination, or in the optimization process and based on the reference field distribution maps, the reference field distribution maps comprising at least one B0 map and at least one B1 map.
